(19) United States
(12) Patent Application Publication
(10) Pub. No.: US 2014/0197434 A1
(43) Pub. Date: Jul. 17, 2014

(54) LIGHT EMITTING DIODE DEVICE AND METHOD FOR MANUFACTURING HEAT DISSIPATION SUBSTRATE

(71) Applicant: ECOCERA OPTRONICS CO., LTD., Taoyuan County (TW)

(72) Inventor: Hung-Pin Lee, Taoyuan County (TW)

(73) Assignee: ECOCERA OPTRONICS CO., LTD., Taoyuan County (TW)

(21) Appl. No.: 13/841,858

(22) Filed: Mar. 15, 2013

(30) Foreign Application Priority Data
Jan. 11, 2013 (TW) 102101195

(51) Int. Cl. H01L 33/64

(52) U.S. Cl. CPC H01L 33/641
USPC 257/98; 29/846

(57) ABSTRACT

The light emitting diode (LED) device includes a substrate formed with at least one electrode; an LED chip disposed on the substrate, and formed with at least one solder pad; at least one wire electrically connected between the solder pad and the electrode; and a fluorescent material layer covering the LED chip. Thermal conductivity of the substrate is 80˜120 W/mK and a color rendering index of the LED device under correlated color temperatures 2600K˜3700K is greater than 90.

### BACKGROUND OF THE INVENTION

1. Technical Field

The invention relates to packaging of light emitting diodes (LEDs), particularly to an LED having a substrate with thermal conductivity below 120 W/mK.

2. Related Art

Light emitting diodes (LEDs) have advantages of low power consumption and long durability. However, with increase of power, luminous efficiency of LEDs will dramatically drop if the heat generated from the LEDs cannot be effectively dissipated. Luminous efficiency of LEDs will reduce with using time and frequencies. An overhigh junction temperature will attenuate luminous efficiency. Thus, heat dissipation becomes a serious problem for development of LEDs.

Substrates with high thermal conductivity can improve heat dissipation effect. There are four kinds of LED substrates, namely printed circuit boards (PCBs), metal core printed circuit boards (MCPCBs), ceramic-based substrates and direct bonding copper (DBC) ceramic substrates. The DBC ceramic substrate is a composite substrate made by sintering a copper foil on a ceramic material. PCBs and MCPCBs can be used in general LEDs. Metal substrates and ceramic substrates must be used when higher unitary heat flux is needed.

Primarily, metal substrates are made of aluminum or copper and can be categorized into a metal base type and a metal core type. Additionally, metal substrates need an insulation layer. On the other hand, the ceramic substrate uses an insulation material such as AlN, SiC and BeO, and thus does not need an additional insulation layer. Because ceramic substrates have higher breakdown voltage, they are suitable for being used in LEDs. Moreover, the ceramic substrates have lower thermal stress and the thermal strain due to better thermal expansion coefficient compatibility.

A common manufacturing method for white LEDs is to use blue LEDs associating with yellow YAG fluorescent powder. However, the LEDs made in above way lacks the components of green light and red light. As a result, the light of the white light LED becomes cool white and warm white light cannot be obtained.

### SUMMARY OF THE INVENTION

An object of the invention is to provide an LED device, which can emit warm white light and has high heat dissipation efficiency. The properties of semiconductors will vary with temperature changes, the energy gap changes when material temperature rises so as to cause the redshift of wavelength.

To accomplish the above object, the light emitting diode (LED) device of the invention includes a substrate including at least one electrode; an LED chip disposed on the substrate and including at least one solder pad; at least one wire, electrically connected between the solder pad and the electrode; and a fluorescent material layer, covering the LED chip. Thermal conductivity of the substrate is 80˜120 W/mK and a color rendering index of the LED device under correlated color temperatures 2600K˜3700K is greater than 90.

The invention also provides another light emitting diode (LED) device including an LED chip, having a first side and a second side opposite thereto; a first electrode and a second electrode, respectively formed on the first side and the second side; a first solder pad and a second solder pad, located on a surface of a substrate, wherein the first solder pad is electrically connected to the first electrode, and the second solder pad is electrically connected to the second electrode; a first pad and a second pad, located on another surface of the substrate; a first conductive rod, located in the substrate and connecting the first solder pad and the first pad; a second conductive rod, located in the substrate and connecting the second solder pad and the second pad; and a fluorescent material layer, covering the second side of the LED chip. Thermal conductivity of the substrate is 80˜120 W/mK and a color rendering index of the LED device under correlated color temperatures 2600K˜3700K is greater than 90.

### BRIEF DESCRIPTION OF THE DRAWINGS

FIG. 1 is a schematic view of the first embodiment of the LED device of the invention;

FIG. 2 is a schematic view of the second embodiment of the LED device of the invention;

FIG. 3 is a schematic view of the third embodiment of the LED device of the invention;

FIG. 4 shows the relationship between the junction temperature and the life of an InGaN LED;

FIG. 5 shows the luminous property of the device B;

FIG. 6 shows the luminous property of the device A; and

FIG. 7 shows the result of adhesion test of the coated copper of the substrates with different sizes and surface structures.

### DETAILED DESCRIPTION OF THE INVENTION

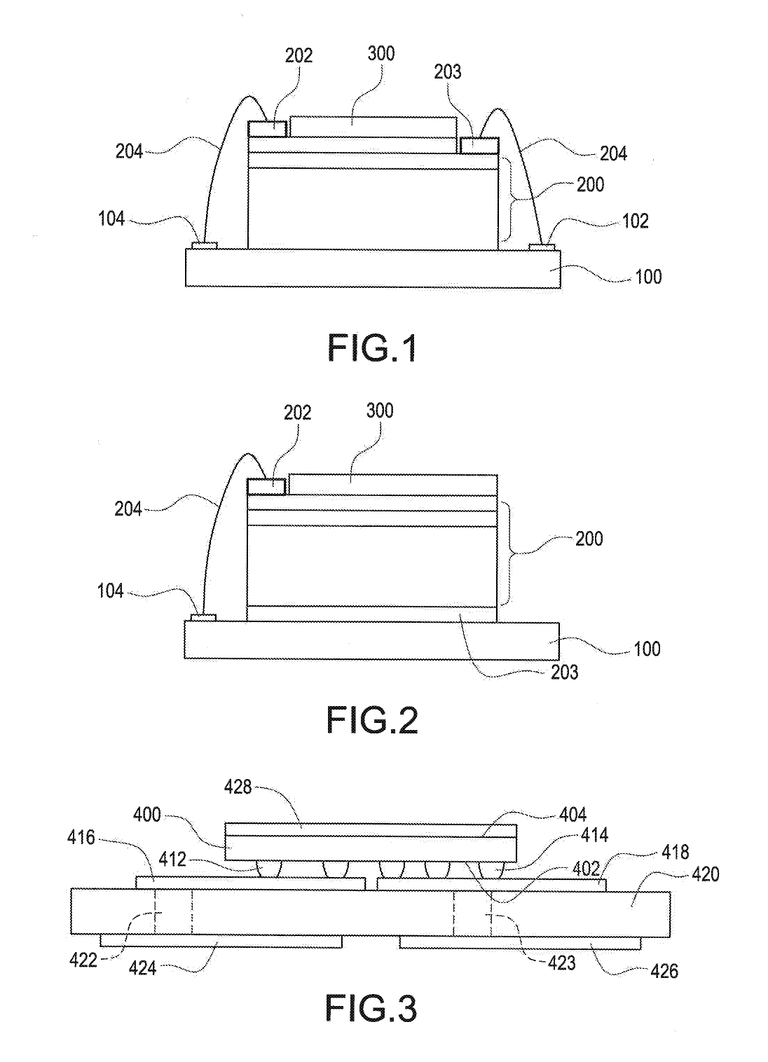

Please refer to FIG. 1. The light emitting diode (LED) device of the invention includes a substrate 100 formed with two electrodes 102, 104; an LED chip 200 disposed on the substrate 100 and formed with two solder pads 202, 203; two wires 204 electrically connected between the solder pads 202, 203 and the electrodes 104, 102, respectively; and a fluorescent material layer 300 covering the LED chip 200. Thermal conductivity of the substrate 100 is 80˜120 W/mK and a color rendering index of the LED device under correlated color temperatures 2600K˜3700K is greater than 90.

The LED chip 200 is adhered on the substrate 100 with adhesive. The substrate 100 may include a metal substrate, a ceramic substrate, a direct bonding copper-coated (DBC) ceramic substrate, a composite material substrate or a semiconductor substrate. The metal substrate is made of at least one of copper and aluminum. The ceramic substrate is made of aluminum oxide, aluminum nitride or zirconium toughened alumina. The composite material substrate is made of silicon nitride or silicon carbide. The semiconductor substrate may be made of silicon. The adhesive may be silver paste, gold-tin solder or their combination. The invention may further include a covering body (not shown) having a seat covering the substrate 100, the LED chip 200, the wires 204 and the fluorescent material layer 300.

The solder pads 202, 203 with different types (P type and N type) are located on the same side of the LED chip 200 but on different planes, and separately on two opposite ends of the top face of the LED chip 200. The wires 204 separately connect the solder pads 202, 203 to the electrodes 104, 102.

Please refer to FIG. 2, which shows the second embodiment of the invention. In this embodiment, the two solder pads 202, 203 are located on different sides of the LED chip 200. The solder pad 202 on the top face of the LED chip 200 is connected to the electrode 104 through the wire 204, and the solder pad 203 on the bottom face of the LED chip 200 is in contact with the substrate 100. This embodiment does not need electrode 102. Thermal conductivity of the substrate 100 is 80˜120 W/mK and a color rendering index of the LED device under correlated color temperatures 2600K˜3700K is greater than 90.

The LED chip 200 is adhered on the substrate 100 with adhesive. The substrate 100 may include a metal substrate, a ceramic substrate, a direct bond copper (DBC) ceramic substrate, a composite material substrate or a semiconductor substrate. The metal substrate is made of at least one of copper and aluminum. The ceramic substrate is made of aluminum oxide, aluminum nitride or zirconia toughened alumina. The composite material substrate is made of silicon nitride or silicon carbide. The semiconductor substrate may be made of silicon. The adhesive may be silver paste, gold-tin solder or their combination. The invention may further include a covering body (not shown) having a seat covering the substrate 100, the LED chip 200, the wires 204 and the fluorescent material layer 300.

Please refer to FIG. 3, which shows the third embodiment of the invention. In this embodiment, the LED device includes an LED chip 400, having a first side 402 and a second side 404 opposite thereto; a first electrode 412 and a second electrode 414, respectively formed on a first area and a second area of the first side 402; a first solder pad 416 and a second solder pad 418 located on a surface of a substrate 420, where the first solder pad 416 is electrically connected to the first electrode 412 and the second solder pad 418 is electrically connected to the second electrode 414; a first pad 424 and a second pad 426 located on another surface of the substrate 420; a first conductive rod 422 located in the substrate 420 and connecting the first solder pad 416 and the first pad 424; a second conductive rod 423 located in the substrate 420 and connecting the second solder pad 418 and the second pad 426; and a fluorescent material layer 428 covering the second side 404 of the LED chip 400. Thermal conductivity of the substrate 420 is 80˜120 W/mK, a color rendering index of the LED device under correlated color temperatures 2600K˜3700K is greater than 90.

The substrate 420 may be a metal substrate, a ceramic substrate, a direct bond copper (DSC) ceramic substrate, a composite material substrate or a semiconductor substrate. The ceramic substrate is made of aluminum oxide, aluminum nitride or zirconia toughened alumina. The composite material substrate is made of silicon nitride or silicon carbide. The semiconductor substrate may be made of silicon.

There are two LED devices A and B to be analyzed. Device A uses an aluminum oxide substrate and device B uses an aluminum nitride substrate, the two devices have the same manufacture parameters except the substrate material. Thermal resistance of devices A and B is 9° C./W and 4° C./W, respectively. Thermal conductivity of aluminum nitride and aluminum oxide is 140˜180 W/mK and 30 W/mK, respectively. According to the above physical quantities, decreasing every 1° C./W of thermal resistance needs to increase thermal conductivity by 30 W/mK.

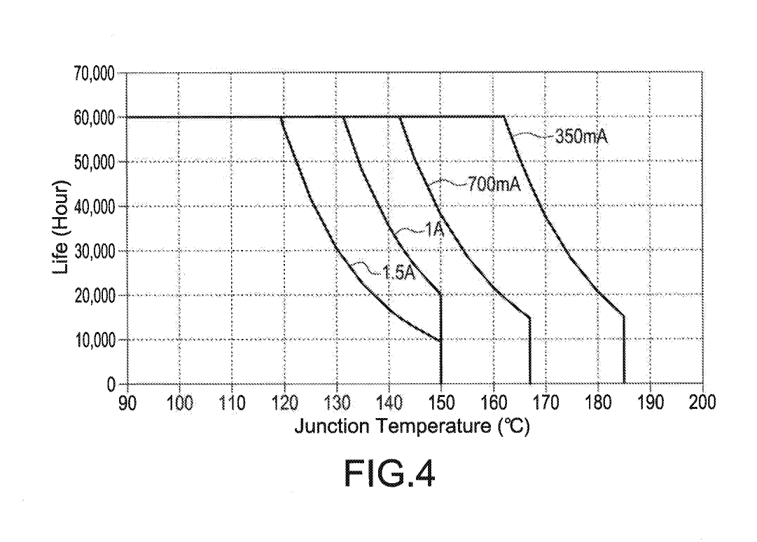

As shown in FIG. 4, products with high power (above 1 A) have a life of 60,000 hours and their junction temperature must be under 132° C. In this embodiment, junction temperature of device A with aluminum oxide and device B with aluminum nitride is 113.35° C. and 103.6° C., respectively. Furthermore, junction temperature of aluminum nitride substrate with thermal conductivity of 100 W/mK will be 114.94° C. by an additional experiment. Thus, using a substrate with thermal conductivity of 100 W/mK can also reach great product durability.

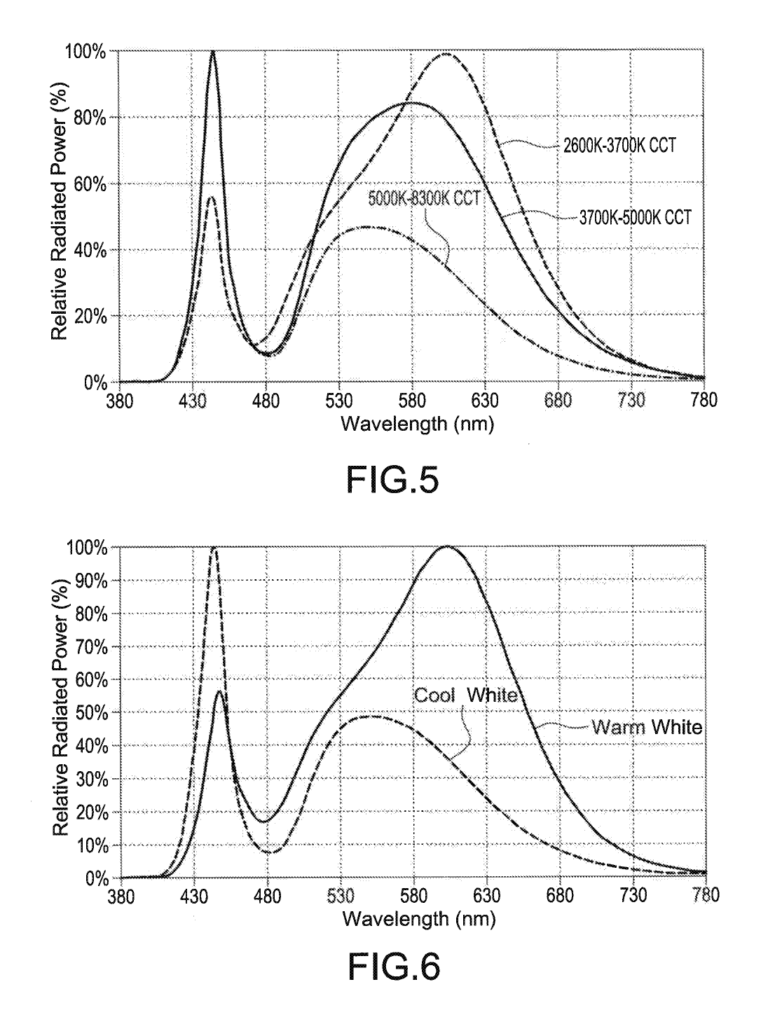

The properties of semiconductor material including LED chip vary with temperature. When temperature is rising, semiconductor material will generate redshift, i.e. the lighting wavelength will be shifted toward longer wavelength (red light). Devices A and B are made by using a blue LED in cooperation with YAG yellow fluorescent powder. Such an LED device cannot emit warm white because it lacks green and red light components. As shown in FIG. 5, warm white spectrum and cool white spectrum of device B within correlated color temperature 2600-3700K do not have obvious difference, so its CRI is 80. As shown in FIG. 6, warm white spectrum of device A obviously moves toward longer wavelength by 20 nm and CRI can reach 90 or more. In other words, white light emitted by device A with a higher junction temperature becomes warmer, and color rendition thereof will be improved.

As a result, using substrate with thermal conductivity of 80-120 W/mK (for example, aluminum nitride with 100 W/mK) to serve as a heat dissipation carrier of LED can not only satisfy the requirement of durability of high power LEDs, but also improve color rendition ability. Furthermore, this can reduce the costs of conventional ceramic substrates by 40%

The invention further provides a manufacturing process for a heat dissipation substrate with thermal conductivity of 80-120 W/mK for a lighting element. The substrates with lower thermal conductivity are affected by grinding or sintering process, so their lattice structure cannot be completely uniform. Accordingly, in a subsequent thin-film process, a metal thin film cannot be formed with a continuous planar structure and finally the adhesion of the metal thin film will be affected. The invention performs a roughening process before the thin-film process so as to make the lattice structure more intact and to enhance the adhesion of the thin film. The mentioned thin-film process is a direct plate copper (DPC) ceramic substrate process, Which includes steps of sputtering a seed layer, performing a photolithography process to form a circuit pattern, electroplating metal circuit, film stripping, etching unnecessary seed layer and performing a surface treatment for circuit.

The method for manufacturing a heat dissipation substrate of a lighting element includes the steps of:

a) providing a substrate with thermal conductivity 80˜120 W/mK;

b) performing a roughening process to the substrate; and

c) forming a circuit pattern on the substrate to serve as the heat dissipation substrate for the lighting element.

The step c) may be implemented by removal method or semi-addition method to form copper circuit. The step b) is implemented by using alkaline liquid such as NaOH or KOH aqueous solution to etch the substrate.

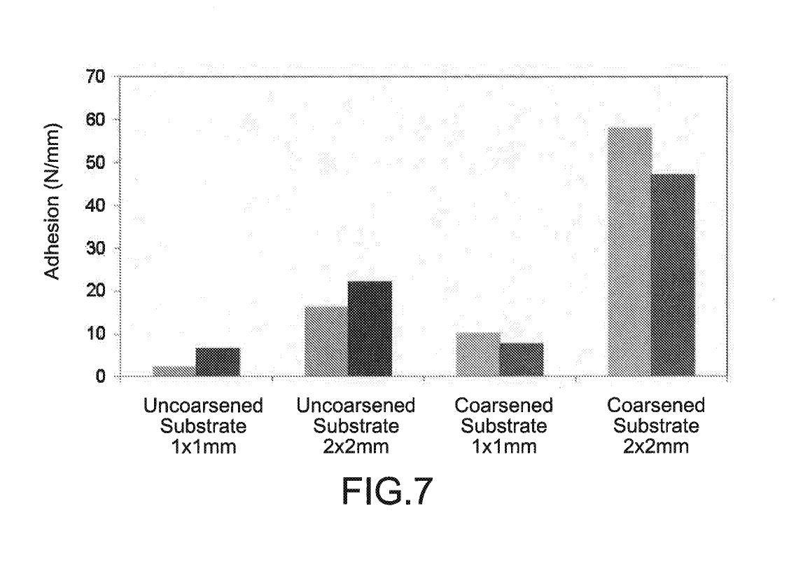

FIG. 7 shows the result of adhesion test of the coated copper of the substrates with different sizes and surface structures. The result shows adhesion of an unroughened substrate is insufficient or very bad, while adhesion of a roughened substrate, either 1×1 mm or 2×2 mm, can be effectively enhanced. Accordingly, the roughening process indeed improves the adhesion of thin film.

It will be appreciated by persons skilled in the art that the above embodiments have been described by way of examples only and not in any limitative sense, and that various alterations and modifications are possible without departure from the scope of the invention as defined by the appended claims.

What is claimed is:

1. A light emitting diode (LED) device comprising:
a substrate including at least an electrode;
an LED chip disposed on the substrate and including at least a solder pad;
at least a wire electrically connected between the solder pad and the electrode; and
a fluorescent material layer covering the LED chip;
wherein thermal conductivity of the substrate is 80˜120 W/mK, and a color rendering index of the LED device under correlated color temperatures 2600K˜3700K is greater than 90.

2. The LED device of claim 1, wherein the solder pad is located on a single side or different sides of the LED chip.

3. The LED device of claim 1, wherein the substrate is made of aluminum nitride or silicon carbide, and thermal conductivity of the substrate is 80˜120 W/mK.

4. The LED device of claim 1, wherein the LED chip is adhered on the substrate with an adhesive.

5. The LED device of claim 1, wherein the substrate includes one selected from a group consisting of a metal substrate, a ceramic substrate, a direct bond copper (DBC) ceramic substrate, a composite material substrate and a semiconductor substrate.

6. The LED device of claim 1, further comprising a covering body having a seat covering the substrate, the LED chip, the wire and the fluorescent material layer.

7. A light emitting diode (LED) device comprising:
an LED chip, having a first side and a second side opposite thereto;
a first electrode and a second electrode respectively formed on a first area and a second area of the first side;
a first solder pad and a second solder pad, located on a surface of a substrate, wherein the first solder pad is electrically connected to the first electrode and the second solder pad is electrically connected to the second electrode;
a first pad and a second pad located on another surface of the substrate;
a first conductive rod located in the substrate and connecting the first solder pad and the first pad;
a second conductive rod located in the substrate and connecting the second solder pad and the second pad; and
a fluorescent material layer covering the second side of the LED chip;
wherein thermal conductivity of the substrate is 80˜120 W/mK, and a color rendering index of the LED device under correlated color temperatures 2600K˜3700K is greater than 90.

8. The LED device of claim 7, wherein the substrate includes one selected from a group consisting of a metal substrate, a ceramic substrate, a direct bond copper (DBC) ceramic substrate, a composite material substrate and a semiconductor substrate.

9. The LED device of claim 7, wherein the substrate is made of aluminum nitride or silicon carbide.

10. The LED device of claim 7, wherein the thermal conductivity of the substrate is 80˜100 W/mK.

11. A method for manufacturing a heat dissipation substrate of a lighting element, comprising steps of:
a) providing a substrate with thermal conductivity of 80˜120 W/mK;
b) performing a roughening process to the substrate; and
c) forming a circuit pattern on the substrate to serve as the heat dissipation substrate for the lighting element.

12. The method of claim 11, wherein the roughening process includes an etching process.

13. The method of claim 12, wherein the etching process includes a step of using an alkaline liquid to etch the substrate.

14. The method of claim 11, wherein the substrate is made of aluminum nitride or silicon carbide.

15. The method of claim 11, wherein the thermal conductivity of the substrate is 80˜100 W/mK.
